(19) United States
(12) Patent Application Publication
(10) Pub. No.: US 2011/0031406 A1
(43) Pub. Date: Feb. 10, 2011

(54) X-RAY DETECTOR AND METHOD FOR PRODUCING AN X-RAY DETECTOR

(76) Inventor: Stefan Wirth, Erlangen (DE)

Correspondence Address: HARNESS, DICKEY & PIERCE, P.L.C., P.O.BOX 8910, RESTON, VA, 20195, US

(21) Appl. No.: 12/849,045

(22) Filed: Aug. 3, 2010

(30) Foreign Application Priority Data
Aug. 4, 2009 (DE) 10 2009 036 079.4

(51) Int. Cl. G01T 1/164; H01L 31/18

(52) U.S. Cl. 250/363.02; 250/366; 438/69; 977/954; 977/773; 257/E31.092

(57) ABSTRACT

An X-ray detector for a tomography device is disclosed, including a plurality of detector elements, each including a photodiode and a scintillator fixed to the optically active surface of the photodiode by a connecting medium. In at least one embodiment, the optically active surface of the photodiode has a nanostructure, which forms a transition region having gradually progressing refractive indices between a refractive index of the connecting medium and a refractive index of the photodiode. Reflections at the optical transition of connecting medium/photodiode and also optical crosstalk to adjacent detector elements are greatly reduced in this way. Such an X-ray detector therefore has a higher luminous efficiency, with which a signal-to-noise ratio and a spatial resolution of the X-ray detector are improved. At least one embodiment of the invention additionally relates to a method for producing an X-ray detector having the properties mentioned.

### PRIORITY STATEMENT

The present application hereby claims priority under 35 U.S.C. §119 on German patent application number DE 10 2009 036 079.4 filed Aug. 4, 2009, the entire contents of which are hereby incorporated herein by reference.

### FIELD

At least one embodiment of the invention generally relates to an X-ray detector and/or a method for producing an X-ray detector.

### BACKGROUND

An X-ray detector for a tomography device, for example for a computed tomography device, serves for the spatially resolved conversion of X-ray radiation into electrical signals which form a starting point for the reconstruction of a tomographic image. For this purpose, the X-ray detector comprises a plurality of detector elements grouped into rows in the Z-direction and columns in the φ-direction. In the case of an indirectly converting variant of an X-ray detector, each detector element has a scintillator, which, at the underside, that is to say at the side remote from the X-ray radiation, is connected to the optically active surface of a photodiode by means of a transparent adhesive.

The X-ray quanta of the X-ray radiation which arrive in the detector element are firstly converted into visible light by the scintillator. The visible light thus generated emerges at the underside of the scintillator, subsequently passes through the transparent adhesive and impinges on the optically active surface of the photodiode, in which the visible light is converted into an electrical signal used for the image reconstruction.

On account of the different refractive indices of scintillator, adhesive and photodiode, the visible light is therefore partly reflected and partly refracted on the way to the photodiode at these two optical transitions in a manner dependent on the angle of incidence. The visible light portion that is reflected away is lost for the generation of an electrical signal. On the other hand, the refracted light in the adhesive layer can be transported to adjacent detector elements, which leads to a lateral optical crosstalk. These two effects mean that the electrical signals generated can represent an intensity of the X-ray radiation arriving in the detector element only with errors.

One possibility for reducing the reflection between adhesive and photodiode is to apply thin antireflection layers, having a thickness of typically λ/4. However, antireflection layers have the disadvantage that they act only in a very narrow wavelength range and therefore have a reflection-reducing effect, in principle, only on a certain portion of the visible light to be detected. Furthermore, the use of antireflection layers is associated with the disadvantage that it is not possible to apply exactly identical layer thicknesses over the entire detector area. Even small tolerances in the layer thicknesses mean that the effective wavelength range and hence the locally effective reduction of the reflection change significantly.

A further possibility for reducing the reflections at the optical transition between the adhesive and the photodiode consists in adapting the refractive index of the adhesive as well as possible to the refractive index of the photodiode, which is generally produced from silicon having a refractive index of approximately 3.3. However, owing to the additional requirements made of X-ray sensitivity, transparency, mechanical stability and processability, such adhesives can only be produced with high costs.

### SUMMARY

In at least one embodiment of the present invention, an X-ray detector for a tomography device is configured such that losses of a detectable scintillation light that are caused by reflection or optical crosstalk are effectively reduced. Furthermore, in at least one embodiment, a method for producing such an X-ray detector is specified.

The X-ray detector according to at least one embodiment of the invention for a tomography device has a plurality of detector elements, each comprising a photodiode and a scintillator fixed to the optically active surface of the photodiode by a connecting medium, wherein the optically active surface of the photodiode has a nanostructure, which forms a transition region having gradually progressing refractive indices between a refractive index of the connecting medium and a refractive index of the photodiode.

The inventor has recognized that, in the case of an indirectly converting X-ray detector, an effective reduction of reflections and of laterally optical crosstalk can be obtained, in particular, only when measures for increasing a luminous efficiency are coordinated very precisely with the optical boundary conditions of the X-ray detector. This is because the visible light generated in the scintillator during the conversion of X-ray radiation is intrinsically diffusely scattered and therefore impinges on the optical transitions in a nondirectional form with different angles of incidence. Therefore, the measures have to be effective for very different angles of incidence. Furthermore, the scintillator emits visible light in a very wide wavelength range, namely between 400 nm and 800 nm. In contrast to the known antireflection layers, therefore, the measures for increasing the luminous efficiency also have to be effective for a very broad spectrum of wavelengths.

It has been recognized here that a reduction of the reflection and of the laterally optical crosstalk for very different angles of incidence and for a broad wavelength range can be effectively obtained when a transition region having gradually progressing refractive indices is present between the refractive index of the connecting medium and the refractive index of the photodiode.

It has furthermore been recognized here that gradual refractive indices can be produced in a very precise form by means of nanostructuring, and that the optically active surface of the photodiode, which is produced from silicon, is particularly well suited to such nanostructuring. In this way it is possible, therefore, to reduce, in particular, losses in the luminous efficiency for the optical transition between connecting medium and photodiode.

In this case, the expression “gradual refractive indices in the transition region” is taken to mean that imaginary layers parallel to the optically active surface of the photodiode have different refractive indices, wherein the refractive indices of the layers have a continuous profile at least in sections as a function of the layer position or with increasing or decreasing distance from the optically active surface of the photodiode.

The nanostructuring therefore produces as it were a fluid transition between the refractive index of the connecting medium and the photodiode. Consequently, the proportion of the visible light that is refracted away and reflected at this interface can be significantly reduced. This leads firstly to an increased luminous efficiency and thus to a better signal-to-noise ratio. At the same time, the laterally optical crosstalk of reflected and refracted light into the adjacent detector elements is reduced, which increases the spatial resolution of the X-ray detector. The increase in the luminous efficiency is effected over the entire wavelength range of the emitted light and, unlike in the case of antireflection layers, is not restricted to a narrow wavelength range. Therefore, differences in the spectral composition of the emitted light, for example owing to light propagation paths of different lengths in the scintillator depending on the interaction location of the X-ray quantum, no longer have such a great effect. A further advantage consists in the fact that the increase in the luminous efficiency is obtained over a very large angular range of the arriving light quanta. This is important for ceramic scintillators, in particular, since these emit in a large angular range at the light exit side.

Gradually progressing refractive indices can be produced in a simple manner particularly when, in one advantageous configuration of the invention, the nanostructure is formed from nanostructure elements arranged in a distributed fashion on the optically active surface of the photodiode, wherein at least some of the nanostructure elements are embodied in a conical fashion. On account of the conical form, different material densities of the material used for forming the nanostructure and hence different refractive indices are obtained with respect to imaginary layers parallel to the optically active surface of the photodiode. Multiple reflections within the nanostructure which arise as a result of the nanostructure elements arranged close together and finally lead to the light being coupled into the photodiode are further effects for forming the gradual progression of the refractive indices in the transition region.

The connecting medium is situated in the intermediate region of the conical nanostructure elements, said connecting medium being used for coupling the scintillator to the photodiode. Since almost exclusively the connecting medium is present in the layers parallel to the photodiode surface in the region of the cone vertices, these layers have a refractive index comparable to the connecting medium. As the distance between the layer and the surface of the photodiode decreases, in the case of a conical embodiment of the nanostructure elements, the proportion of the material from which the nanostructure elements is constructed increases. Therefore, in that region of the photodiode which is near the surface, the layers have a refractive index comparable to the material of the nanostructure. This is the case particularly when the conical nanostructure elements are arranged on the surface of the photodiode in such a way that the base areas of the cones are arranged against one another, that is to say without a gap, with respect to one another.

In one example embodiment, the nanostructure, in the same way as the photodiode, is produced from silicon, in particular from hydrogenated amorphous silicon, such that in this case the layers near the surface with respect to the photodiode have a refractive index comparable to the photodiode. This ensures, therefore, that the refractive indices of layers of the nanostructure that are near the surface directly adjoin the refractive index of the photodiode.

As an alternative thereto, in a further advantageous configuration of at least one embodiment of the invention, at least some of the nanostructure elements are embodied in a cylindrical fashion. Cylindrical elements, in the same way as the conical elements, have no undercut. Such structure elements can therefore be formed step-by-step in a simple manner in a production process and are therefore particularly well suited to the construction of nanostructures.

In one advantageous configuration of at least one embodiment of the invention, at least some of the nanostructure elements are embodied with different heights. By virtue of different heights of the cylinders, layers parallel to the photodiode surface have, in a manner dependent on the number, the arrangement density and the height difference of the cylinders, refractive indices which are matched to the refractive index of the connecting medium in a stepped manner with increasing distance from the photodiode surface. In this way it is possible, in particular, to form the progression of the refractive indices with different gradients within the transition region. Consequently, by way of example, a parabolic progression of the refractive indices can be produced as a gradual progression. This has the advantage, in particular, that the gradual progression, in a manner dependent on the expected intensity of the scintillation light in the different wavelength ranges, in order to obtain a high luminous efficiency, has a smaller gradient in specific refractive index ranges than in the other ranges.

The nanostructure is preferably produced by a dry etching method, in particular a reactive ion etching method. Such a production method makes it possible to form the nanostructure in a very controlled and precise form by step-by-step removal of a material applied in layered fashion.

In the method of at least one embodiment for producing an X-ray detector comprising detector elements, each comprising a photodiode, a nanostructure is produced at an optically active surface of the photodiode in order to form a transition region having gradually progressing refractive indices according to the following method steps:
a) producing a mask on the optically active surface of the photodiode or on a silicon layer produced thereon with nanoparticles,
b) removing material at unmasked regions by means of dry etching,
c) removing the mask,
d) applying a connecting medium, and
e) fixing a scintillator to the optically active surface of the photodiode by means of the connecting medium.

In accordance with at least one embodiment of the method, therefore, the nanostructure can be etched directly from the silicon of the photodiode from the surface thereof. A method step according to which a separate silicon layer has to be applied to the surface of the photodiode is therefore obviated in this case. As a result of the direct structuring of the optically active surface of the photodiode, a further optical transition, namely between the applied layer and the photodiode, and further light losses possibly associated with the transition are therefore avoided.

SiO₂ particles of identical size are preferably used as nanoparticles for forming the mask.

Preferably a transparent adhesive, in particular an epoxy resin adhesive, is used as the connecting medium. Such an adhesive is easy to process, resistant to X-rays and has the required strength for the positionally accurate fixing of the two components photodiode and scintillator.

### BRIEF DESCRIPTION OF THE DRAWINGS

Example embodiments of the invention are explained in greater detail below with reference to schematic drawings, in which:

FIG. 1 shows a tomography device in a perspective illustration which, in part, is like a block diagram,

FIG. 2 shows, in a perspective view, an excerpt from the X-ray detector,

FIG. 3 shows, in a sectional illustration perpendicular to the photodiode surface, an X-ray detector with a nanostructure having conical elements,

FIG. 4 shows, in the illustration form from FIG. 3, an X-ray detector with a nanostructure having cylindrical elements,

FIG. 5 shows a first method step for producing a nanostructure,

FIG. 6 shows a second method step for producing a nanostructure,

FIG. 7 shows a third method step for producing a nanostructure, and

FIG. 8 shows a fourth method step for producing a nanostructure.

Mutually corresponding parts and variables are always provided with the same reference symbols in all of the figures.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

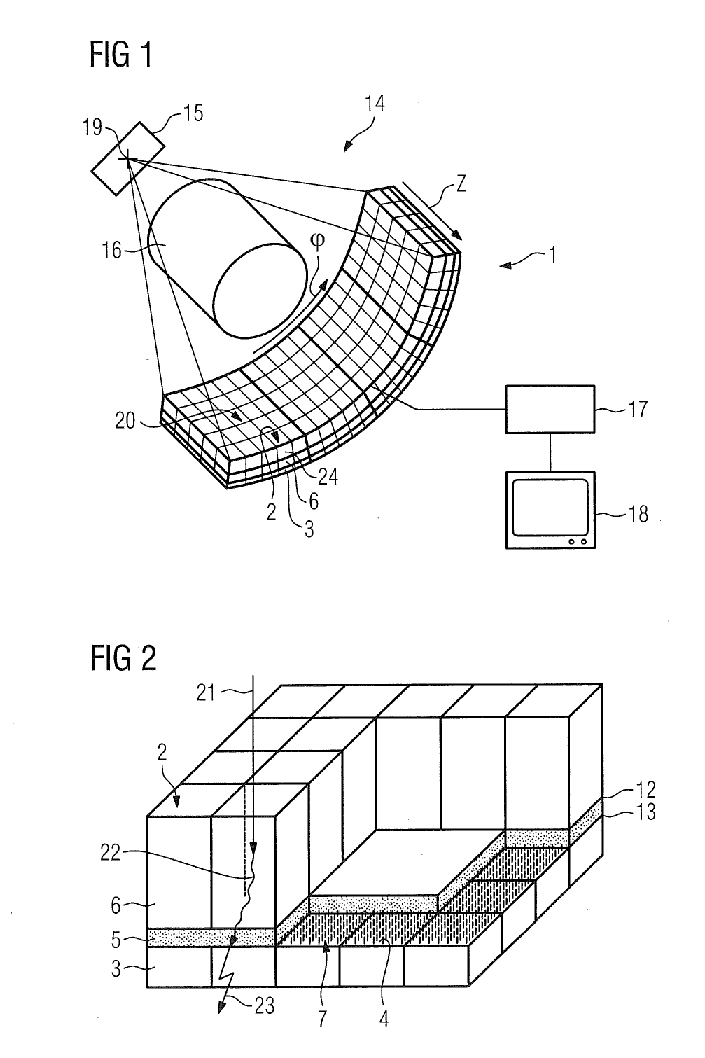

FIG. 1 shows a tomography device 14, here in the form of a computed tomography device, in a perspective illustration which, in part, is like a block diagram. Situated in the interior of the computed tomography device 14 is a recording system 1, 15, which is arranged such that it is rotatable about a Z-axis on a gantry (not illustrated) and by which projections from a multiplicity of different projection directions can be detected from an object 16, for example a patient. The projections obtained are communicated to a computing unit 17 and computed step-by-step to form a tomographic image, for example a slice image or volume image, and displayed on a display unit 18.

The recording system 1, 15 comprises, as essential components, an emitter 15 in the form of an X-ray tube and an X-ray detector 1 arranged opposite the latter. The X-ray tube 15 generates, proceeding from a focus 19, X-ray radiation in the form of a fan-shaped X-ray beam, which penetrates through the measurement region of the recording system 1, 15 and subsequently impinges on the X-ray detector 1 and is converted by the latter to form a set of electrical signals.

For this purpose, the X-ray detector 1 has a plurality of detector modules 20—four in the present example—which are arranged alongside one another in the φ-direction and only one of which is provided with a reference symbol. Each of the detector modules comprises, as illustrated for the sake of better visibility in an excerpt in FIG. 2, detector elements 2 lined up in rows in the Z-direction and in columns in the φ-direction, a respective collimator 24 being arranged in front of said detector elements in order to screen out stray radiation, only one element respectively being provided with a reference symbol for reasons of clarity. The conversion of the X-ray radiation 21 into an electrical signal 23 is effected for each detector element 2 by means of a scintillator 6 indirectly by way of the generation of visible light 22, which is detected by a photodiode 3. For this purpose, the scintillator 6 is coupled to the optically active surface 4 of a photodiode 3 by means of a transparent adhesive 5, in this example by means of an epoxy resin adhesive, which has the function of a connecting medium.

The visible light 22 generated in the scintillator 6 typically has a wavelength range of approximately 400 nm to approximately 800 nm and, on the way to the photodiode 3, passes through two optical transitions 12, 13, namely firstly the scintillator-adhesive transition 12 and secondly the adhesive-photodiode transition 13. Scintillator 6, adhesive 5 and photodiode 3 have different refractive indices. The refractive index of the scintillator 6 is approximately 2.5, that of the adhesive 5 is approximately 1.5 and that of the photodiode 3 is approximately 3.3. Without further measures, particularly at the optical transition 13 of adhesive-photodiode, at which there is the greatest jump in the refractive index, the visible light 22 generated would be greatly reflected and/or refracted, the associated light losses leading firstly to a deterioration of the signal-to-noise ratio and secondly to a reduced spatial resolution on account of the optical crosstalk.

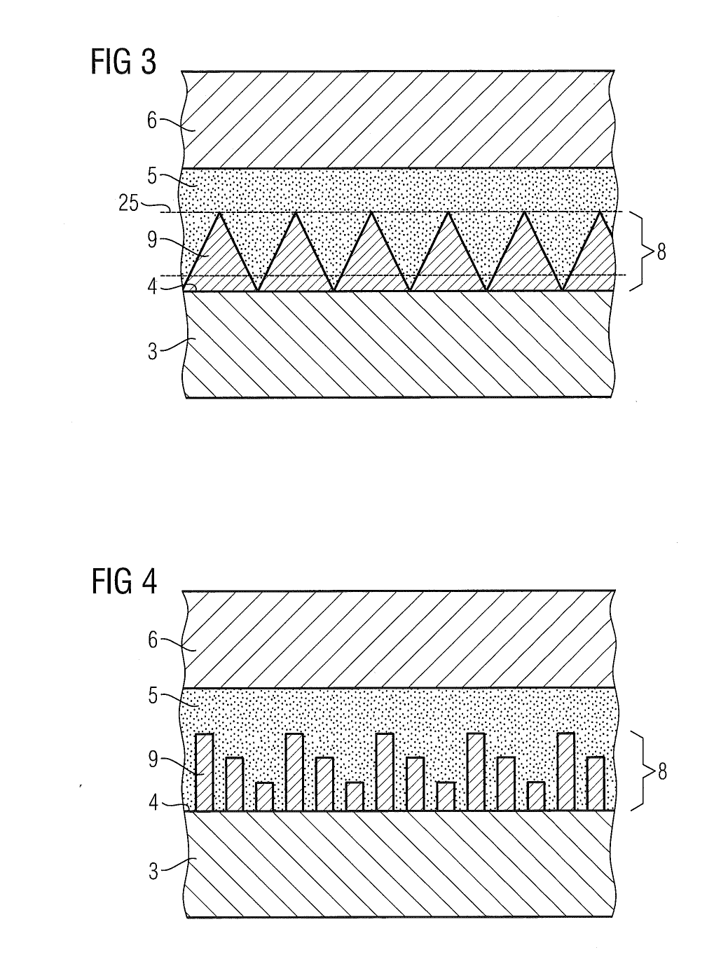

For this reason, the optically active surface 4 of the photodiode 3 has a nanostructure 7, by means of which a transition region 8 having gradually progressing refractive indices is produced, said transition region being shown in FIGS. 3 and 4. The reflection and the light refraction for the wavelength range of the scintillation light are considerably reduced as a result of the gradual progression of the refractive indices. This leads to an increase in the luminous efficiency and thus to an improved signal-to-noise ratio and a better spatial resolution.

FIGS. 3 and 4 show, by way of example, nanostructures composed of silicon which comprise a multiplicity of nanostructure elements 9 arranged on the optically active surface 4 of the photodiode 3. It is possible to use completely different shapings of the nanostructure elements 9 for forming a gradual refractive index progression. In FIG. 3, which shows a section through the X-ray detector 1 perpendicular to the surface of the photodiode 3, the nanostructure elements 9, only one of which is provided with a reference symbol, have a conical shape, for example, wherein the base areas of the cones directly adjoin one another on the surface 4 of the photodiode 3. The adhesive 5 is situated in the interspaces between the cones. A first imaginary layer 25 parallel to the surface 4 of the photodiode 3 in the region of the cone vertices substantially contains the adhesive 5 and therefore has a refractive index comparable to the adhesive 5. As the distance between the layer and the surface 4 decreases, the proportion of the area occupied by the cones becomes continuously larger. The layers therefore increasingly have silicon, such that the refractive index of these layers in the transition region 8 is continuously matched to the refractive index of the photodiode 3. Furthermore, gradual progressions of the refractive indices are also produced by multiple reflections between the nanostructure elements 9, which finally lead to the visible light being coupled into the photodiode 3.

FIG. 4 shows, in the illustration form of FIG. 3, a nanostructure 7 constructed from nanostructure elements 9 having a cylindrical shape. The cylinders have three different heights in this example. Different material compositions in layers parallel to the surface 4 of the photodiode 3 and also multiple reflections of the light diffusely incident on the nanostructure 7 have the effect of considerably reducing the light losses as a result of reflection, in particular.

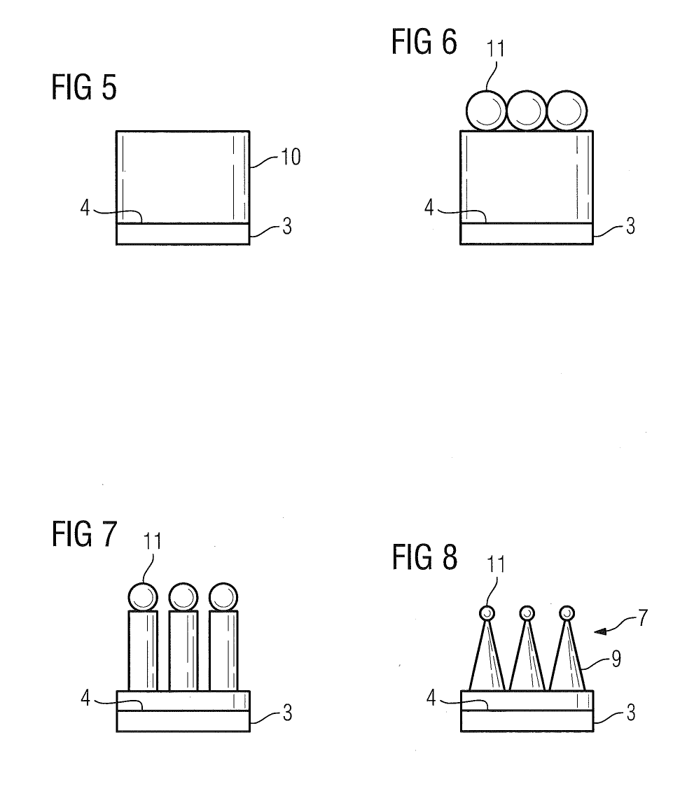

FIGS. 5 to 8 show four different stages of a dry etching method, here in particular of a reactive ion etching method, for producing the nanostructure 7. Firstly, as shown in FIG. 5, a silicon layer 10, here a hydrogenated amorphous silicon, is applied to the optically active surface 4 of the photodiode 3. However, it would also be conceivable for the nanostructure 7 to be structured directly from the surface 4 of the photodiode 3, such that the application of the silicon layer 10 would be obviated in this case. In a next step, for passivation or for masking, nanoparticles 11 here in the form of silicon oxide balls of identical size, are applied to the silicon layer 10, as shown in FIG. 6, at specific positions, only one nanoparticle 11 being provided with a reference symbol. Afterward, as shown in FIGS. 7 and 8, silicon is removed step-by-step from the unmasked regions of the silicon layer 10. The etching effect is brought about by the impact of accelerated ions of a plasma, which is generated on the basis of sulfur hexafluoride, onto the silicon layer, both physical and chemical etching processes leading to material removal. For this purpose, sulfur hexafluoride in a carrier gas, for example argon, is held in a plasma state in the alternating field between two capacitor plates, wherein ground potential is applied to one capacitor plate and a wafer is attached, said wafer being configured for forming the photodiodes of an X-ray detector. An alternating field is applied to the opposite capacitor plate. During a cycle of the alternating voltage, the readily mobile electrons firstly migrate to this capacitor plate as long as the positive voltage is present. Since the electrons can no longer leave said plate after the voltage reversal, since not enough energy is supplied for this purpose, a great accumulation of negative charge arises there. Therefore, this results in a very high static field (bias voltage), which also has an effective accelerating effect on the heavy and thus sluggish ions. Consequently, the accelerated ions impinge on the silicon layer 10 and manifest their physical etching effect possibly in association with a chemical reaction. After a plurality of etching steps have been performed, the nanoparticles 11 are finally removed from the nanostructure 7 formed. Afterward, as shown in FIG. 2, an adhesive 5 is applied, by means of which the scintillator 6 is fixed on the photodiode 3.

To summarize, the following can be stated:

An embodiment of the invention relates to an X-ray detector for a tomography device 14 comprising a plurality of detector elements 2, each comprising a photodiode 3 and a scintillator 6 fixed to the optically active surface 4 of the photodiode 3 by a connecting medium 5, wherein the optically active surface 4 of the photodiode 3 has a nanostructure 7, which forms a transition region 8 having gradually progressing refractive indices between a refractive index of the connecting medium 5 and a refractive index of the photodiode 3. Reflections at the optical transition 13 of connecting medium/photodiode and also optical crosstalk to adjacent detector elements 2 are greatly reduced in this way. Such an X-ray detector 1 therefore has a higher luminous efficiency, with which a signal-to-noise ratio and a spatial resolution of the X-ray detector 1 are improved. The invention additionally relates to a method for producing a photodiode and an X-ray detector 1 having the properties mentioned.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, computer readable medium and computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a computer readable medium and is adapted to perform any one of the aforementioned methods when run on a computer device (a device including a processor). Thus, the storage medium or computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. Examples of the built-in medium include, but are not limited to, rewriteable non-volatile memories, such as ROMs and flash memories, and hard disks. Examples of the removable medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An X-ray detector for a tomography device, comprising:
a plurality of detector elements, each including
a photodiode, and
a scintillator, fixed to an optically active surface of the photodiode by a connecting medium, the optically active surface of the photodiode including a nanostructure which forms a transition region including gradually progressing refractive indices between a refractive index of the connecting medium and a refractive index of the photodiode.

2. The X-ray detector as claimed in claim 1, wherein the nanostructure is formed from nanostructure elements arranged in a distributed fashion on the optically active surface of the photodiode.

3. The X-ray detector as claimed in claim 2, wherein at least some of the nanostructure elements are embodied in a conical fashion.

4. The X-ray detector as claimed in claim 2, wherein at least some of the nanostructure elements are embodied in a cylindrical fashion.

5. The X-ray detector as claimed in claim 2, wherein at least some of the nanostructure elements are embodied with different heights.

6. The X-ray detector as claimed in claim 1, wherein the nanostructure is produced from silicon of a layer applied to the optically active surface of the photodiode.

7. The X-ray detector as claimed in claim 1, wherein the nanostructure is produced directly from silicon of the photodiode.

8. The X-ray detector as claimed in claim 1, wherein the nanostructure is produced by a dry etching method.

9. The X-ray detector as claimed in claim 1, wherein the connecting medium is a transparent adhesive.

10. A method for producing an X-ray detector comprising detector elements, each including a photodiode, a nanostructure being produced at an optically active surface of the photodiode in order to form a transition region including gradually progressing refractive indices, the method comprising:
producing a mask on the optically active surface of the photodiode or on a silicon layer produced thereon with nanoparticles;
removing material at unmasked regions by way of dry etching;
removing the mask;
applying a connecting medium; and
fixing a scintillator to the optically active surface of the photodiode via the connecting medium.

11. The method as claimed in claim 10, wherein reactive ion etching is used as dry etching.

12. The method as claimed in claim 10, wherein SiO₂ particles of identical size are used as nanoparticles.

13. The X-ray detector as claimed in claim 3, wherein at least some of the nanostructure elements are embodied in a cylindrical fashion.

14. The X-ray detector as claimed in claim 3, wherein at least some of the nanostructure elements are embodied with different heights.

15. The X-ray detector as claimed in claim 4, wherein at least some of the nanostructure elements are embodied with different heights.

16. The X-ray detector as claimed in claim 6, wherein the nanostructure is produced from hydrogenated amorphous silicon.

17. The X-ray detector as claimed in claim 7, wherein the nanostructure is produced directly from crystalline silicon.

18. The X-ray detector as claimed in claim 8, wherein the nanostructure is produced by a reactive ion etching method.

19. The X-ray detector as claimed in claim 9, wherein the connecting medium is an epoxy resin adhesive.

20. The method as claimed in claim 11, wherein SiO₂ particles of identical size are used as nanoparticles.
